(19) United States
(12) Patent Application Publication
(10) Pub. No.: US 2007/0126111 A1
(43) Pub. Date: Jun. 7, 2007

(54) Microelectronic packaging and components

(76) Inventors: Uri Mirsky, Nofit (IL); Shimon Neftin, Kiryat Shmonah (IL); Lev Furer, Haifa (IL); Nina Sezin, Haifa (IL); Leonid Dukhovny, Migdal Ha'emek (IL)

Correspondence Address: EITAN LAW GROUP;c/o LANDONIP, INC., 1700 DIAGONAL ROAD, SUITE 450, ALEXANDRIA, VA, 22314, US

(21) Appl. No.: 11/585,255

(22) Filed: Oct. 24, 2006

Related U.S. Application Data
(63) Continuation of application No. 10/536,354, filed on May 26, 2005, now abandoned.

(51) Int. Cl. H01L 23/12

(52) U.S. Cl. 257/700; 257/E23.069

(57) ABSTRACT

The present invention is for substrates for use in interposes for electronic packaging purposes. One preferred embodiment of the present invention is a substrate for use in a Spring Connector Matrix (SCM) interposer having an array of electrically insulated spring connectors each having a fixed end portion and a floating end portion resiliently flexibly coupled to its associated fixed end portion and capable of being independently displaceable in a plane substantially perpendicular to the SCM interposer's major surfaces. Another preferred embodiment of the present invention is a substrate intended to be folded along one or more predetermined fold lines or forming a 3D interposer. Folding is intended at wings which may be wholly formed of valve metal material or may include one or more electrically insulated valve metal traces electrically connected to one or more interconnect regions intended for ICs either single or double sided mounted thereon.

### FIELD OF THE INVENTION

The invention relates to microelectronic packaging and components.

### BACKGROUND OF THE INVENTION

Interposers including inter alia pin grid arrays (PGAs), ball grid arrays (BGAs), and chip-scale packages (CSPs) are employed for coupling one or more chips to a printed circuit board or a power and/or voltage source. Such interposers are required to electrically, mechanically, and thermally couple between two substantially different media which typically have different mechanical and thermal behavior and also different input/output (I/O) interconnection pitches.

In Applicant's PCT International Application No. PCT/IL98/00230 published under WO98/53499 entitled “Substrate for Electronic Packaging, Pin Jig Fixture”, the entire contents of which are incorporated herein by reference, there is illustrated and described a substrate for electronic packaging, and a pin jig fixture for manufacturing same. The substrate has a discrete, generally prismatoid, initially electrically conductive valve metal solid body with one or more spaced apart original valve metal vias each individually electrically insulated by a porous oxidized body portion therearound.

In Applicant's PCT International Application No. PCT/IL99/00633 published under WO00/31797 entitled “Device for Electronic Packaging Pin Jig Fixture”, the entire contents of which are incorporated herein by reference, there is illustrated and described a device for electronic packaging, and a pin jig fixture for manufacturing same. A device may include vias similar to those in Applicant's aforementioned WO98/53499 and/or other trace designs. Applicant's WO00/31797 also illustrates and describes multi-layer devices, and electronic packaging including BGA interposers.

### SUMMARY OF THE INVENTION

The first aspect of the present invention is directed toward a substrate for use in a Spring Connector Matrix (SCM) interposer suitable for electrical packaging purposes. The SCM interposer includes an array of electrically insulated spring connectors each having a fixed end portion and a floating end portion resiliently flexibly coupled to its associated fixed end portion and capable of being independently displaceable in a plane substantially perpendicular to the SCM interposers major surfaces. The fixed end portions and the floating end portions can be provided with different types of electrically conductive elements including inter alia balls, bumps, and the like, depending on the intended application of a SCM interpose. Intended applications of a SCM interposer include inter alia an ultrasound transducer, a probe card, and the like. Various active and/or passive circuit elements may be incorporated into a SCM interposer as illustrated and described in Applicant's aforementioned WO00/31797.

The second aspect of the present invention is directed toward a substrate capable of being folded along at least one predetermined fold line into a three dimensional (3D) interposer for electronic packaging purposes. The substrate includes at least one interconnect region intended for the mounting of one or more integrated chips (ICs) thereon either in a single or double sided manner, and at least one non-interconnect region or so-called wing for folding along a predetermined fold line to render angular disposed first and second non-interconnect region portions. A non-interconnect region may be entirely of valve metal in which case it is inherently capable of being folded once or even more. Alternatively, a non-interconnect region may include one or more electrically insulated elongated valve metal traces whose longitudinal axes are generally perpendicular to a fold line. Such traces are electrically insulated by valve metal oxide which is a relatively brittle material and therefore which may crack on folding but this will not affect the intended purpose of its intended 3D interposer since the elongated valve metal traces will still remain intact. An intended 3D interposer can have a relatively simple structure, say, a single non-interconnect region to be folded with respect to a single interconnect region or a complicated multi-storey structure for considerably reducing the footprint of a relatively large substrate. 3D interposers not only afford smaller footprint but they also facilitate improved heat sink design, and EMI shielding. The 3D interposer also facilitates an efficient process for manufacturing electronic packages, the process including either one side or two sided lapping of ICs to a uniform height depending on whether the ICs are single or double sided mounted on a 3D interposer.

### BRIEF DESCRIPTION OF THE DRAWINGS

In order to understand the invention and to see how it may be carried out in practice, preferred embodiments will now be described, by way of non-limiting examples only, with reference to the accompany drawings in which similar parts are likewise numbered, and in which:

FIG. 1 is a top view of a first preferred embodiment of a Spring Connector Matrix (SCM) interposer prior to solder masking and without electrically conductive pads;

FIG. 2 is a cross section view of the SCM interposer of FIG. 1 along line A-A after solder masking;

FIGS. 3A-3L illustrate the process for manufacturing the SCM interposer of FIG. 1;

FIG. 4 is a top view of a second preferred embodiment of a SCM interposer also prior to solder masking;

FIG. 5 is a cross section view of the SCM interposer of FIG. 4 along line C-C after solder masking;

FIG. 6 is a cross section view of an ultrasound transducer including the SCM interposer of FIG. 1;

FIG. 7 is a cross section view of a probe card including the SCM interposer of FIG. 1;

FIG. 8 is a side view of a BGA electronic package;

FIG. 9 is a top view of a substrate for folding into the BGA electronic package of FIG. 8;

FIG. 10 is a cross section view of the substrate of FIG. 9 along line D-D;

FIGS. 11A-11E illustrate the process for manufacturing the electronic package of FIG. 8;

FIG. 12 is a perspective view of a two-storey 3D interposer;

FIG. 13 is a top view of an L-shaped substrate for folding along three predetermined fold lines into the 3D interposer of FIG. 12;

FIG. 14 is a cross section view of a bus of the substrate of FIG. 13 along line E-E; and

FIG. 15 is a side view of a BGA electronic package including the 3D interposer of FIG. 12 along line of sight F.

### DETAILED DESCRIPTION OF PREFERRED EMBODIMENTS

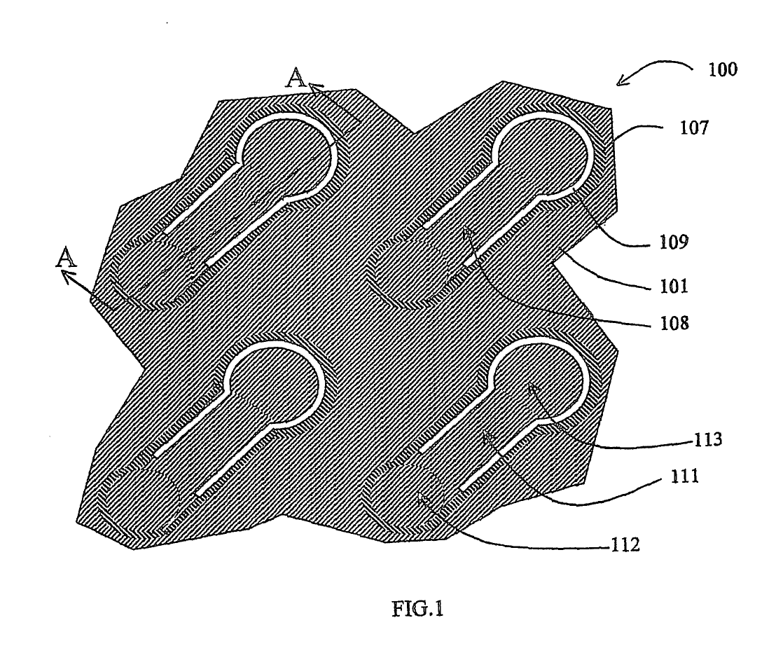

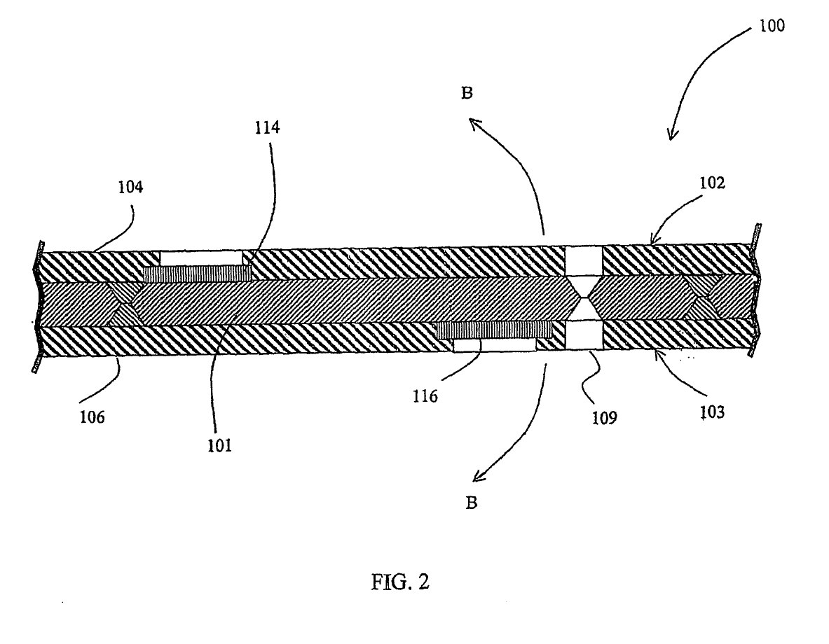

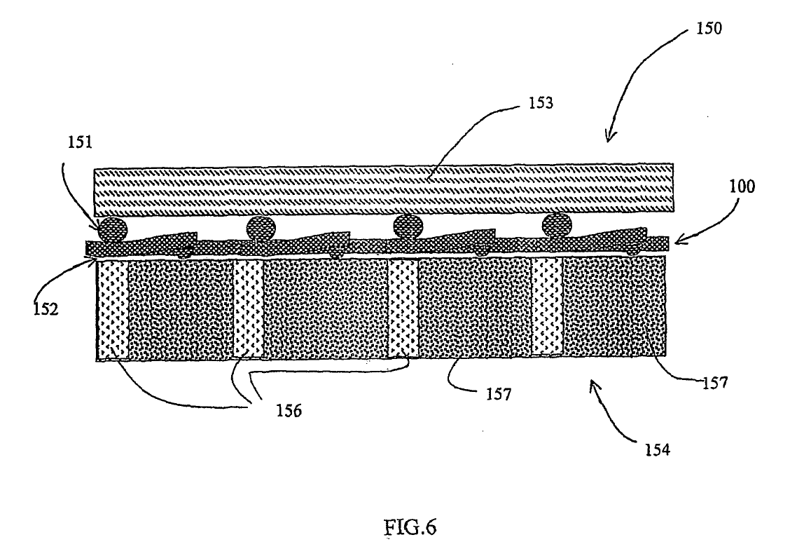

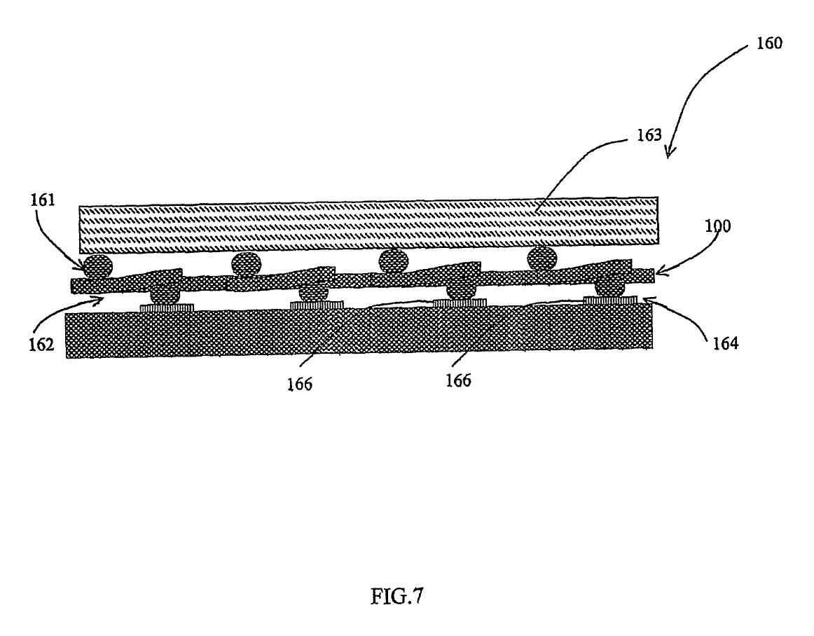

FIGS. 1 and 2 show a Spring Connector Matrix (SCM) interposer 100 suitable for packaging a range of electronic devices including an ultrasound transducer (see FIG. 6), a probe card (see FIG. 7), and other devices. The SCM interposer 100 includes a discrete, generally prismatoid, primarily valve metal substrate 101 intimately sandwiched between solder mask and signal layers 102 and 103 having major surfaces 104 and 106. The substrate 101 includes an array of keyhole shaped perimeter walls 107 (constituting surrounds) each electrically insulating an elongated valve metal insert 108. The thickness of the perimeter wall 107 is of at least 50 microns in the plane of the major surfaces 104 and 106.

The SCM interposer 100 includes an array of throughgoing cavities 109 perpendicularly extending between the major surfaces 104 and 106. The throughgoing cavities 109 are positioned so as to be internally coextensive with a major portion of each perimeter wall 107 for converting inserts 108 into spring connectors 111 each having a fixed end portion 112 rigidly connected to its defining perimeter wall 107 and a cantilever floating end portion 113 inherently resiliently flexibly coupled to its associated fixed end portion 112. Thus, a SCM interposer's floating end portions 113 are independently displaceable with respect to its fixed end portions 112 in a plane substantially perpendicular to its major plane as shown by arrows B. Each fixed end portion 112 is provided with an electrically conductive pad 114 and each floating end portion 113 is provided with an electrically conductive pad 116 for electrical connection of a SCM interposer 100 with external electronic components and devices. The SCM interposer 100 may be provided with various active and/or passive circuit elements as illustrated and described in Applicant's aforementioned WO01/31797.

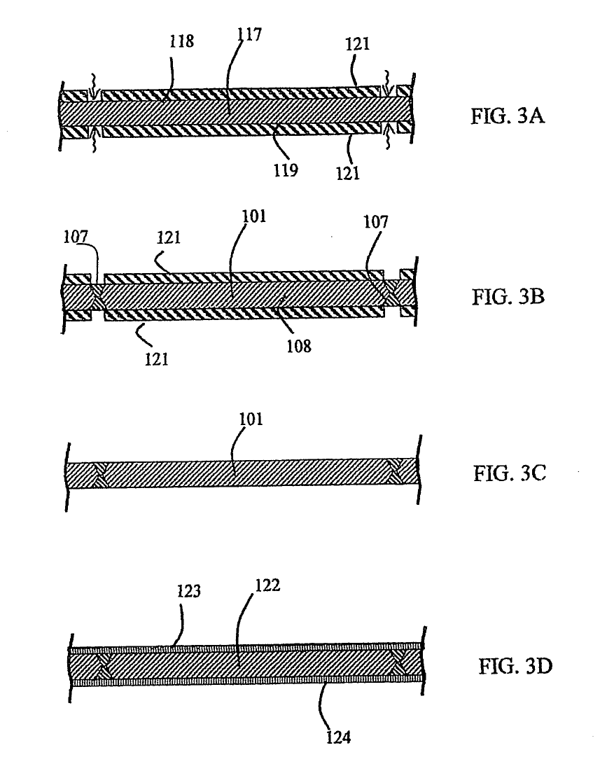

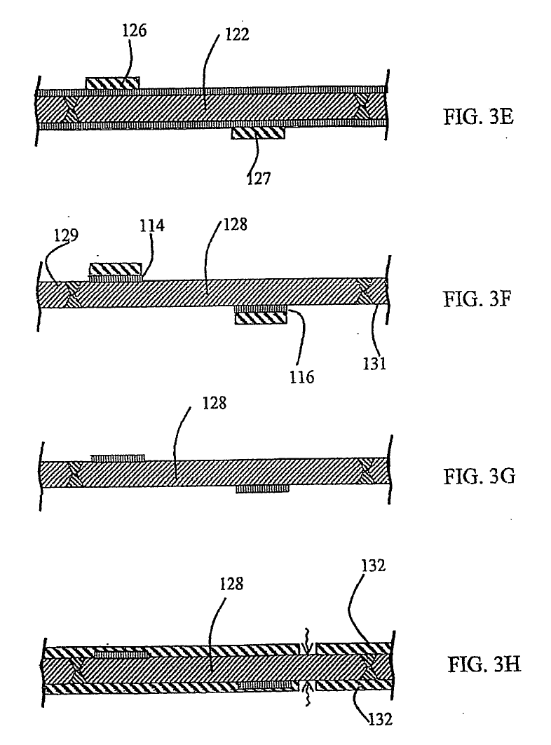

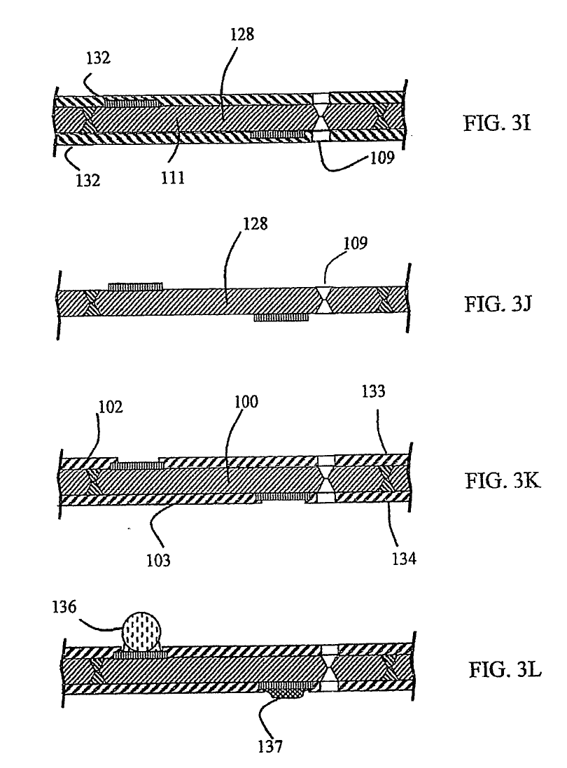

The process for the manufacture of a SCM interposer 100 is now described with reference to FIGS. 3A-3L starting from a discrete, generally prismatoid, non-layered valve metal blank 117 with opposing generally parallel major surfaces 118 and 119: A first pair of mirror photoresist masks 121 are applied in registration to the valve metal blanks major surfaces 118 and 119 (see FIG. 3A). The masked valve metal blank 117 undergoes a low voltage dual-sided porous anodization to form the largely valve metal substrate 101 with the keyhole shaped perimeter walls 107 extending generally perpendicular to the substrate's major surfaces 118 and 119 for defining the elongated valve metal inserts 108 (see FIG. 3B). The photoresist masks 121 are removed (see FIG. 3C) and the largely valve metal substrate 101 undergoes copper deposition to cover its major surfaces with copper to form an intermediate product 122 with major surfaces 123 and 124 (see FIG. 3D). A pair of different photoresist masks 126 and 127 are applied to the intermediate products major surfaces 123 and 124 (see FIG. 3E) and the masked intermediate product 122 undergoes copper etching to form an intermediate product 128 with major surfaces 129 and 131 respectively having electrically conductive pads 114 and electrically conductive pads 116 (see FIG. 3F). The photoresist masks 126 and 127 ale removed (see FIG. 3G) and a second pair of mirror photoresist masks 132 are applied in registration to the intermediate products major surfaces 129 and 131 (see FIG. 3H). The masked intermediate product 128 undergoes aluminum etching to form the throughgoing cavities 109 defining the spring connectors 111 (see FIG. 3I). The photoresist masks 132 are removed (see FIG. 3J) and solder masks 133 and 134 are applied to the intermediate products major surfaces 129 and 131 to form the SCM interposer's solder mask and signal layers 102 and 103 (see FIG. 3K). The SCM interposer 100 can be provided with balls 136 attached to its electrically conductive pads 114 and electrically conductive pads 116 or, alternatively, balls 136 can be replaced by lighter bumps 137 depending on the intended application of a SCM interposer 100 (see FIG. 3L).

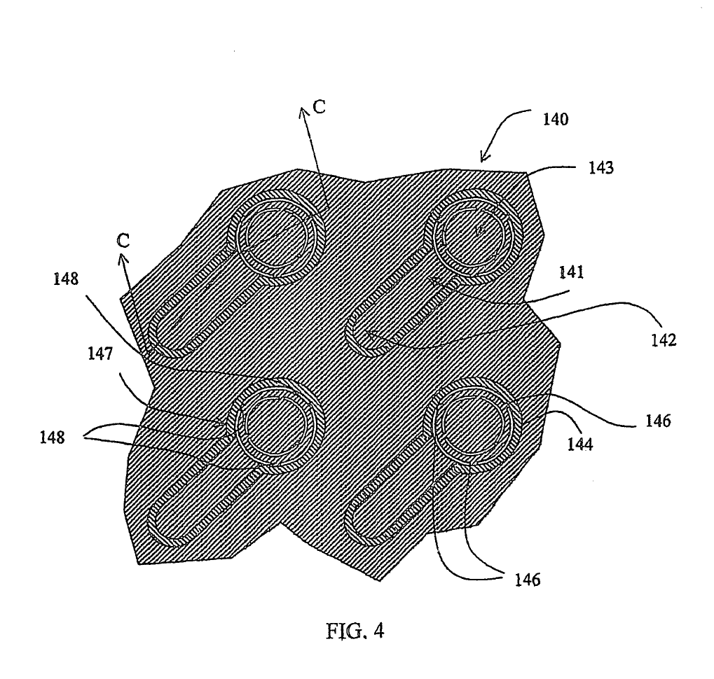

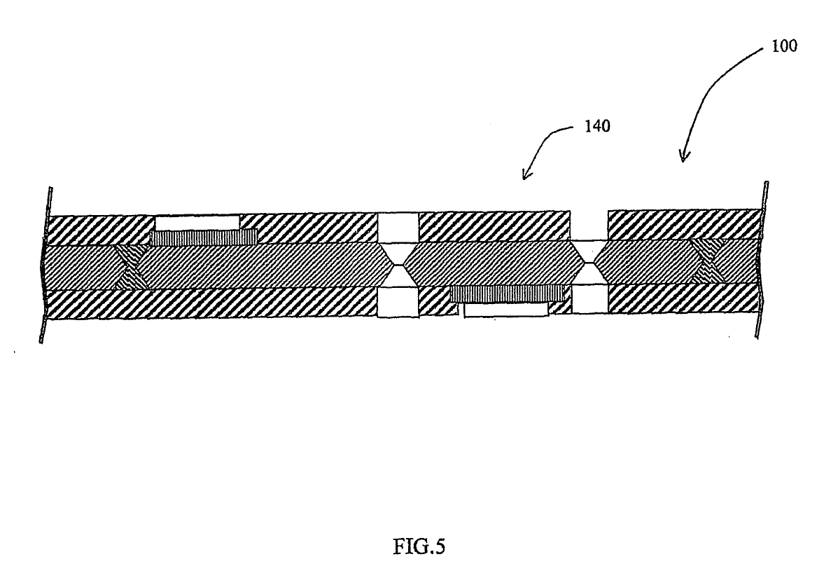

FIGS. 4 and 5 show a Spring Connector Matrix (SCM) interposer 140 similar to the SCM interposer 100 insofar as it also includes an array of spring connectors 141 each having a fixed end portion 142 and a floating end portion 143. The difference between the SCM interposer 140 and the SCM interposer 100 is that the former's floating end portions 143 are floatingly supported by an inner circle 144 of three resiliently flexible equidistanced tethers 146 which are in turn floating supported by an outer circle 147 of three resiliently flexible equidistanced tethers 148 connecting the inner circle 144 to the remainder of the spring connector 141. This tethering arrangement better contains lateral movement of the floating end portions 143 in the plane of SCM interposer 140 than the cantilevering arrangement but allows less movement of the floating end portions 143 in the plane perpendicular thereto. The SCM interposer 140 is manufactured using the same process as the SCM interposer 100 except in this case the aluminum etching step of FIG. 3H employs a pair of different photoresist masks for rendering the floating end portions 143 rather than the cantilever floating end portions 113.

FIG. 6 shows an ultrasound transducer 150 including a SCM interposer 100 including an array of balls 151 attached to its electrically conductive pads 114 and an array of bumps 152 attached to its electrically conductive pads 116, a rigid control board 153 and an acoustic matrix 154 including a polymer substrate 156 with an array of independently operative acoustic elements (constituting electronic components) 157. The control board 153 is soldered onto the array of balls 151 whilst each acoustic element 157 is individually soldered to a bump of the array of bumps 152 whereby each acoustic element 157 is capable of independent mechanical vibratory motion perpendicular to the plane of the SCM interposer 100 in response to its individual electrical stimulation.

FIG. 7 shows a probe card 160 including a SCM interposer 100 including an array of balls 161 attached to its electrically conductive pads 114 and an array of balls 162 attached to its electrically conductive pads 116, a rigid control board 163, and a probe card 164 including an array of independently operative test pads (constituting electronic components) 166. The control board 163 is soldered onto the array of balls 161 whilst each test pad 166 is individually soldered to a bump of the array of bumps 162 whereby each test pad 166 is capable of independent displacement perpendicular to the plane of the SCM interposer 100.

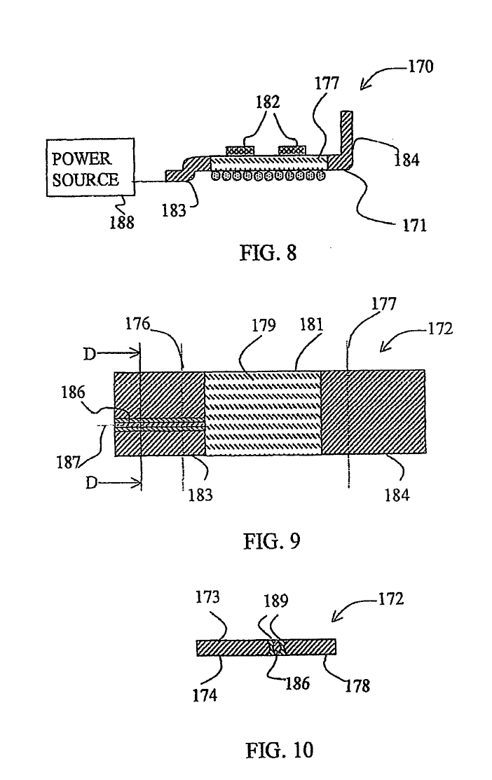

FIGS. 8-10 show a BGA electronic package 170 including a 3D BGA interposer 171 folded from a substrate 172 having a pair of opposing generally parallel major surfaces 173 and 174 along a pair of predetermined fold lines 176 and 177. The substrate 172 includes a discrete, generally prismatoid, initially entirely valve metal non-layered solid body 178 formed into an interconnect region 179 having an imaginary generally rectangular perimeter 181 in a top view of the substrate's major surfaces 173 and 174. The fold lines 176 and 177 are parallel to opposite sides of the perimeter 181 and displaced therefrom by a relatively short distance of a few millimeters. The interconnect region 179 includes electrically insulated valve metal traces constituting active and/or passive electronic devices as illustrated and described in Applicant's aforementioned WO00/31797 and has a pair of ICs 182 mounted single sided thereon.

The substrate 172 includes a primarily valve metal non-interconnect region 183 adjacent to one end of the interconnect region 179 and a wholly valve metal non-interconnect region 184 adjacent to the opposite end of the interconnect region 179. The non-interconnect region 183 includes an electrically insulated valve metal trace 186 having a longitudinal axis 187 substantially perpendicular to the fold line 176 and designed to connect the interconnect region 179 to, say, a power source 188. The valve metal trace 186 is preferably electrically insulated by a pair of elongated valve metal oxide walls 189 generally perpendicularly extending between the major surfaces 173 and 174. The valve metal oxide walls 189 are preferably formed by a dual sided porous anodization step simultaneously with the forming of the interconnect region 179.

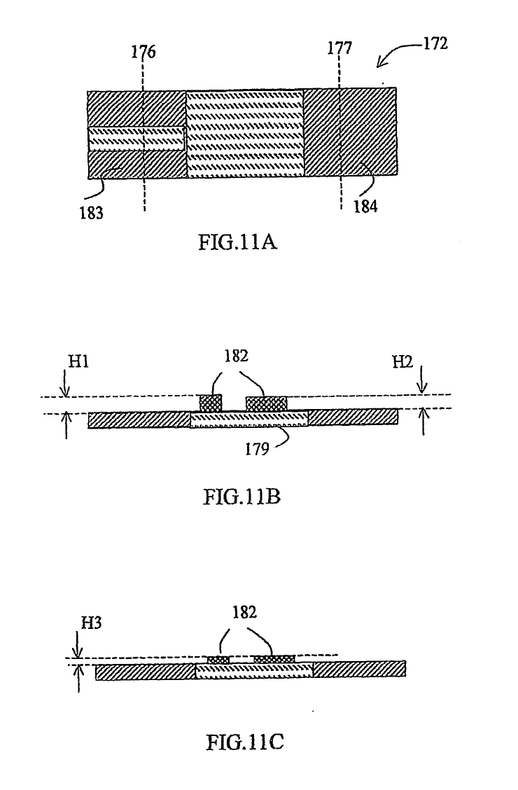

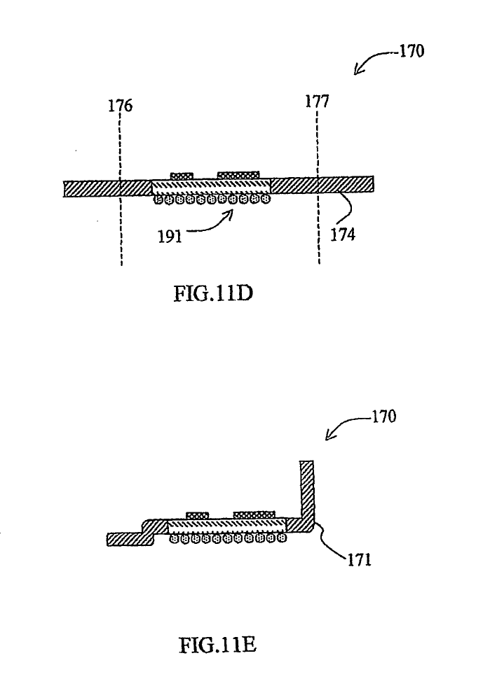

The process for the manufacture of the electronic package 170 is now described with reference to FIGS. 11A-11E starting from the substrate 172. ICs 182 of different heights H1 and H2 where H1>H2 are mounted on the interconnect region 179 (see FIG. 11B). The ICs 182 are one-sided lapped to a uniform height ID (see FIG. 11C). The substrate's major surface 174 is provided with balls 191 (see FIG. 11D). The substrate 172 is folded along the fold lines 176 and 177 to form the 3D BGA interposer 171 (see FIG. 11E).

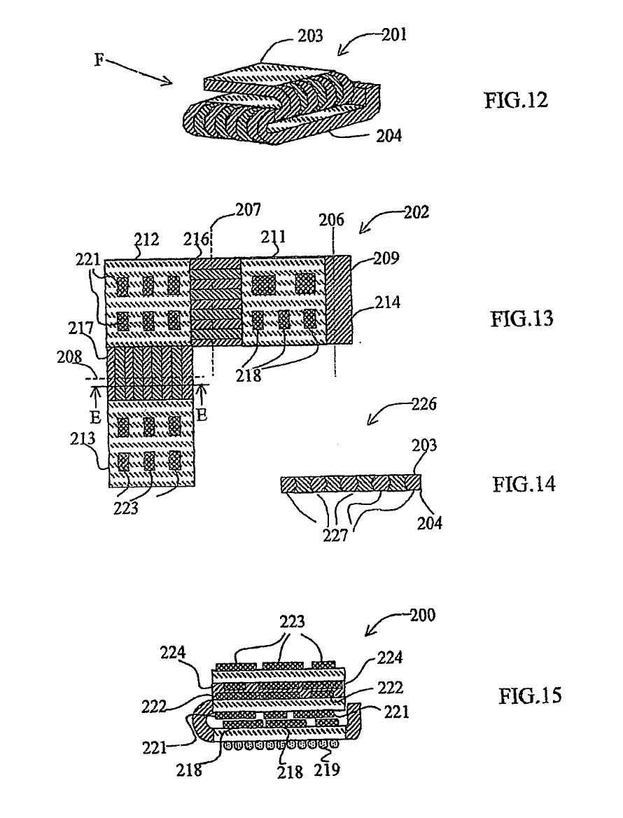

FIGS. 12-15 show a BGA electronic package 200 including a two storey 3D BGA interposer 201 folded from an L-shaped substrate 202 having a pair of opposing generally parallel major surfaces 203 and 204 along three fold lines 206, 207 and 208. The substrate 202 includes a discrete, generally prismatoid, initially entirely valve metal non-layered solid body 209 formed into three interconnect regions 211, 212 and 213, a wholly valve metal non-interconnect region 214, and a pair of primarily valve metal non-interconnect regions 216 and 217. The interconnect region 211 is provided with ICs 218 on the substrate's upper surface 203, and balls 219 on the substrate's lower surface 204. The interconnect region 212 is provided with ICs 221 mounted on the substrate's upper surface 203, and ICs 222 mounted on the substrates lower surface 204. The interconnect region 213 is provided with ICs 223 mounted on the substrate's upper surface 203, and ICs 224 mounted on the substrate's lower surface 204. The non-interconnect regions 216 and 217 are similar to the non-interconnect region 183 but differ therefrom insofar as they each include a bus 226 of electrically insulated valve metal traces 227 rather than a single valve metal trace.

While the invention has been described with respect to a limited number of embodiments, it will be appreciated that many variations, modifications, and other applications of the invention can be made within the scope of the appended claims.

1. A substrate for use in a Spring Connector Matrix (SCM) interposer for electronic packaging purposes, the substrate comprising a discrete, generally prismatoid, initially entirely valve metal non-layered solid body having a pair of opposing generally parallel major surfaces and an array of valve metal oxide surrounds each extending generally perpendicularly between said major surfaces and electrically insulating an elongated valve metal insert initially being a contiguous portion of said solid body prior to the anodization of said solid body to form said array of porous valve metal oxide surrounds.

2. The substrate according to claim 1 wherein a surround is constituted by a relatively thin perimeter wall having a thickness of at least 50 microns in the plane of the major surfaces.

3. The substrate according to either claim 1 or 2 wherein an insert has a keyhole shape in a top view of one of the substrate's major surfaces.

4. A SCM interposer comprising a substrate according to any one of claims 1 to 3 intimately sandwiched between a pair of solder mask and signal layers having a pair of major surfaces, and an array of spring connectors each formed from an elongated valve metal insert of said substrate's array of elongated valve metal inserts by one or more throughgoing cavities perpendicularly extending between the SCM interposer's major surfaces,
each spring connector having a fixed end portion rigidly connected to its defining surround and a floating end portion resiliently flexibly coupled to its associated fixed end portion whereby said floating end portion is displaceable relative to said fixed end portion in a plane substantially perpendicular to the SCM interposers major surfaces, and said fixed end portion and said floating end portion each having an electrically conductive pad on opposite surfaces of the SCM interposers major surfaces for electrical connection therebetween via their associated spring connector.

5. The SCM interposer according to claim 4 wherein a spring connector includes a cantilever floating end portion.

6. The SCM interposer according to claim 4 wherein a spring connector includes an array of resiliently flexible tethers substantially equidistantly disposed around its floating end portion for resiliently flexibly coupling to its fixed end portion.

7. An electronic device comprising a SCM interposer according to any one of claims 1 to 6, a rigid control board soldered to said electrically conductive pads of said fixed end portions, and an array of independently operative electronic elements attached to said electrically conductive pads of said floating end portions.

8. An ultrasound transducer according to claim 7 wherein said array of independently operative electronic elements are acoustic elements.

9. A probe card according to claim 7 wherein said array of independently operative electronic elements are test pads.

10. A process for manufacturing a Spring Connector Matrix (SCM) interposer for electronic packaging purposes, the SCM interposer having major surfaces, the process comprising the steps of:
(a) providing a discrete, generally prismatoid, valve metal non-layered solid blank having a pair of opposing generally parallel major surfaces;
(b) applying both said major surfaces of the solid blank with photoresist masks with at least one of said major surfaces being selectively masked;
(c) anodizing the masked solid blank to form an array of valve metal oxide surrounds each extending generally perpendicularly between the blank's major surfaces and electrically insulating an elongated valve metal insert initially being a contiguous portion of the solid body; and
(d) providing one or more throughgoing cavities perpendicularly extending between the SCM interposer's major surfaces to convert each valve metal insert into a spring connector having a fixed end portion rigidly connected to its defining surround and a floating end portion resiliently flexibly coupled to its associated fixed end portion whereby the floating end portion is displaceable relative to the fixed end portion in a plane substantially perpendicular to the SCM interposer's major surfaces.

11. The process according to claim 10 wherein a surround is constituted by a relatively thin perimeter wall having a thickness of at least 50 microns in the plane of the major surfaces.

12. The process according to either claim 10 or 11 wherein an insert has a keyhole shape in a top view of one of the substrate's major surfaces.

13. The process according to any one of claims 10 to 12 wherein step (d) includes the step of etching at least valve metal to form the throughgoing cavities.

14. The process according to any one of claims 10 to 12 wherein step (d) includes the step of mechanical removing at least valve metal to form the throughgoing cavities.

15. A substrate capable of being folded along at least one predetermined fold line for use in a three dimensional (3D) interposer for electronic packaging purposes, the substrate comprising a discrete, generally prismatoid, initially entirely valve metal non-layered solid body including a pair of opposing generally parallel major surfaces and including an interconnect region having an imaginary generally rectangular perimeter in a top view of one of the substrates major surfaces,
said interconnect region having a plurality of valve metal oxide surrounds each extending generally perpendicularly between said major surfaces and electrically insulating valve metal regions initially being contiguous portions of said solid body prior to the anodization of said solid body to form said plurality of porous valve metal oxide surrounds whereby said interconnect region is capable of having one or more integrated chips (ICs) single or double sided mounted thereon,
a predetermined fold line of the at least one predetermined fold line being parallel to a side of said perimeter and displaced therefrom and passing through a non-interconnect region contiguous to said interconnect region prior to the anodization of said solid body to form said plurality of porous valve metal oxide surrounds, and being either of solid valve metal or having at least one valve metal oxide surround each extending generally perpendicularly between said major surfaces and electrically insulating an elongated valve metal trace electrically connected with said interconnect region and having a longitudinal axis generally perpendicular to the predetermined fold line whereby the substrate is capable of being folded along the predetermined fold line to form a 3D interposer.

16. The substrate according to claim 15 wherein said non-interconnect region includes a bus of electrically insulated elongated valve metal traces each electrically connected with said interconnect region and having a longitudinal axis generally perpendicular to the predetermined fold line.

17. The substrate according to claim 16 wherein a bus of elongated valve metal traces connects a pair of said interconnect regions.

18. An electronic package comprising a 3D interposer folded from a substrate according to any one of claims 15 to 17 whereby a non-interconnect region includes a first portion and a second portion angularly disposed with respect thereto.

19. The electronic package according to claim 18 wherein an interconnect region has ICs mounted double sided thereon.

20. A process for manufacturing an electronic package including a three dimensional (3D) interposer folded from a substrate according to any one of claims 15 to 17, the process comprising the steps of:
(a) providing a substrate according to any one of claims 15 to 17;
(b) mounting at least one IC onto the substrate;
(c) lapping the at least one IC to a uniform height; and
(d) folding the substrate to form the 3D interposer.

21. The process according to claim 20 wherein step (c) includes double sided lapping of ICs double sided mounted on the substrate.
